(19) United States
(12) Patent Application Publication
(10) Pub. No.: US 2010/0139731 A1
(43) Pub. Date: Jun. 10, 2010

(54) WIRE-BASED HANGING WIRE-WAY FOR PHOTOVOLTAIC MODULES OR MODULE GROUPS

(76) Inventor: Charles Almy, Berkeley, CA (US)

Correspondence Address: SunPower/ BSTZ;Blakely Sokoloff Taylor & Zafman LLP, 1279 OAKMEAD PARKWAY, SUNNYVALE, CA, 94085-4040, US

(21) Appl. No.: 12/396,290

(22) Filed: Mar. 2, 2009

(51) Int. Cl. H01L 31/042; F16L 3/08

(52) U.S. Cl. 136/244; 248/58

(57) ABSTRACT

A wire-based hanging wire-way for photovoltaic modules or module groups is described. A photovoltaic system includes a first and a second photovoltaic module group. A wire-based hanging wire-way is coupled with the first and the second photovoltaic module groups. A first bundle of electrical cables is supported by the wire-based hanging wire-way. One or more electrical cables from the first bundle of electrical cables are coupled to the first photovoltaic module group. The photovoltaic system also includes a power distribution network adapted to receive a second bundle of electrical cables, the second bundle of electrical cables including the first bundle of electrical cables. Further, one or more electrical cables from the second bundle of electrical cables is coupled to the second photovoltaic module group.

This invention was made with Government support under Contract No. DEFC36-07GO17043 awarded by the United States Department of Energy. The Government has certain rights in this invention.

### TECHNICAL FIELD

Embodiments of the present invention are in the field of photovoltaic systems and, in particular, wire-based hanging wire-ways for photovoltaic modules or module groups and methods for supporting bundles of electrical cables between photovoltaic modules or module groups.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of the substrate creates electron and hole pairs in the bulk of the substrate, which migrate to p-doped and n-doped regions in the substrate, thereby generating a voltage differential between the doped regions. The doped regions are coupled to metal contacts on the solar cell to direct an electrical current from the cell to an external circuit coupled thereto. Generally, an array of solar cells, each solar cell interconnected, is mounted on a common or shared platform to provide a photovoltaic module. A plurality of photovoltaic modules or module groups may be electrically coupled to an electrical power distribution network, forming a photovoltaic system.

Ground based power distribution networks require significant cabling between photovoltaic modules or discrete groups of modules, such as trackers or rows. To meet electrical code, the cabling is usually placed in a metal wire tray or conduit. However, metal wire trays or conduits can be both expensive and cumbersome to build. Accordingly, additional improvements are needed in the evolution of photovoltaic systems which include arrays of photovoltaic modules and ground based power distribution networks. For example, on Dec. 17, 2007, SunPower® Corp. of San Jose, Calif. announced completion of a solar photovoltaic system at Nellis Air Force Base. In that photovoltaic system, a rigid bar drive strut was used to support bundled electrical cables with wire-ties attached to the rigid bar drive strut.

### BRIEF DESCRIPTION OF THE DRAWINGS

FIG. 1 illustrates a diagram of a photovoltaic system, including a wire-based hanging wire-way for photovoltaic modules of the photovoltaic system, in accordance with an embodiment of the present invention.

FIG. 2A illustrates an isometric view of a portion of a wire-based hanging wire-way for photovoltaic modules in a photovoltaic system, in accordance with an embodiment of the present invention.

FIG. 2B illustrates an isometric view of a portion of a wire-based hanging wire-way for photovoltaic modules in a photovoltaic system, in accordance with an embodiment of the present invention.

FIG. 3 illustrates an isometric view of a photovoltaic module group assembled on a tracker and an associated post, in accordance with an embodiment of the present invention.

FIG. 4 depicts a Flowchart representing a series of operations in a method for supporting a bundle of electrical cables between photovoltaic modules, in accordance with an embodiment of the present invention.

FIG. 5 depicts a Flowchart representing a series of operations in a method for supporting a bundle of electrical cables between photovoltaic modules, in accordance with an embodiment of the present invention.

FIG. 6 illustrates a diagram of a photovoltaic system, including a plurality of wire-based hanging wire-ways for photovoltaic module groups of the photovoltaic system, in accordance with an embodiment of the present invention.

### DETAILED DESCRIPTION

A wire-based hanging wire-way for photovoltaic modules or module groups and methods for supporting a bundle of electrical cables between photovoltaic modules or module groups are described herein. In the following description, numerous specific details are set forth, such as specific measurements, in order to provide a thorough understanding of the present invention. It will be apparent to one skilled in the art that embodiments of the present invention may be practiced without these specific details. In other instances, well-known fabrication operations, such as solar cell array assembly operations, are not described in detail in order to not unnecessarily obscure embodiments of the present invention. Furthermore, it is to be understood that the various embodiments shown in the Figures are illustrative representations and are not necessarily drawn to scale.

Disclosed herein is a wire-based hanging wire-way for photovoltaic modules or module groups. A photovoltaic system may include a first photovoltaic module group and a second photovoltaic module group. In one embodiment, a wire-based hanging wire-way is coupled with the first and the second photovoltaic module groups. A first bundle of electrical cables is supported by the wire-based hanging wire-way. One or more electrical cables from the first bundle of electrical cables are coupled to the first photovoltaic module group. The photovoltaic system also includes a power distribution network adapted to receive a second bundle of electrical cables, the second bundle of electrical cables including the first bundle of electrical cables. Further, one or more electrical cables from the second bundle of electrical cables is coupled to the second photovoltaic module group. A method may include supporting a bundle of electrical cables between photovoltaic modules. In one embodiment, the method includes coupling, to form a bundle of electrical cables, one or more electrical cables to a first photovoltaic module group. A wire-based hanging wire-way is coupled with the first photovoltaic module group and with a second photovoltaic module group. The bundle of electrical cables is then suspended between the first and second photovoltaic module groups by coupling the bundle of electrical cables to the wire-based hanging wire-way. In another embodiment, the method includes coupling to form a bundle of electrical cables, one or more electrical cables to a first photovoltaic module group. The bundle of electrical cables is coupled to a wire-based hanging wire-way. The bundle of electrical cables is then suspended between the first photovoltaic module group and a second photovoltaic module group by coupling the wire-based hanging wire-way with the first and second photovoltaic module groups.

In any photovoltaic system, electrical installation cables are routed from point to point. Often these points are far from one another and a system may require that the electrical cables be supported at more locations than the point to point locations. In an aspect of the present invention, a wire-based hanging wire-way may be used to support, by suspending, electrical cables for photovoltaic modules in a photovoltaic system. In accordance with an embodiment of the present invention, instead of an expensive metal wire tray, a wire-based hanging wire-way is used between photovoltaic modules to support a bundle of electrical cables coupled to the photovoltaic modules. In an additional embodiment, a wire-based hanging wire-way is used between one of the photovoltaic modules and a ground based power distribution network to support, by suspending, the bundle of electrical cables between an array of photovoltaic modules and the power distribution network. By using a wire-based hanging wire-way, a photovoltaic system may be easier and more cost-effective to install.

The use of a wire-based hanging wire-way when installing a photovoltaic system may enable flexibility of design of the photovoltaic system. For example, in accordance with an embodiment of the present invention, by using a wire-based hanging wire-way versus, say, a pre-wound electrical cable and support wire system, specific needs of the photovoltaic system can be met. In one embodiment, by using a wire-based hanging wire-way, electrical cables do not have to be pulled on or pinched, the system is not limited to a particular number of electrical cables, and a faulty electrical cable within a bundle of electrical cables is more easily replaced. Such on-site customizable support for a bundle of electrical cables may not be available “off-the-shelf” commercially. In accordance with an embodiment of the present invention, a wire-based hanging wire-way is flexible, providing more range of motion and compatibility with on-site customizable support than, say, a rigid bar drive strut having wire-ties coupled thereto.

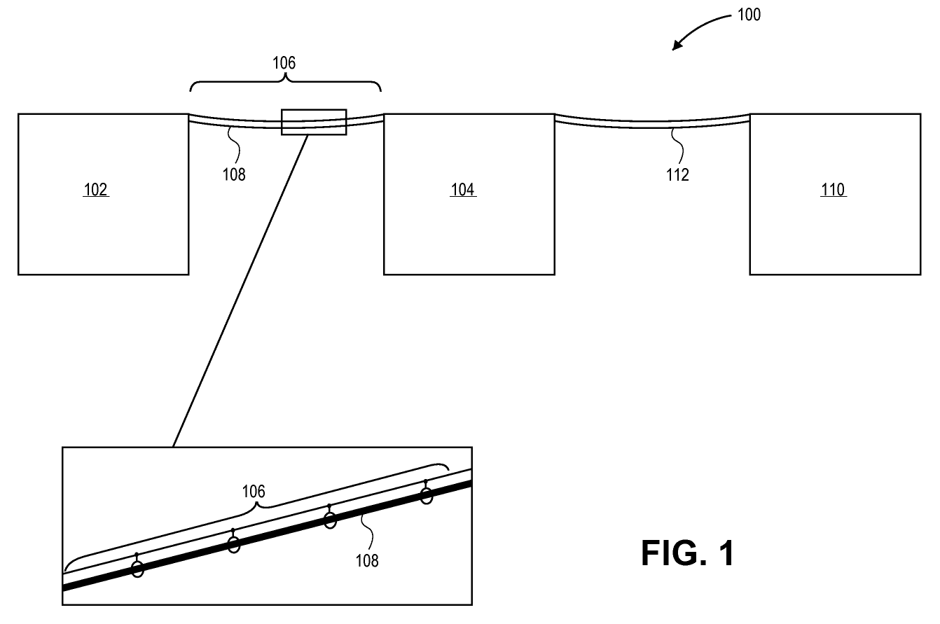

In an aspect of the present invention, a wire-based hanging wire-way is included in a photovoltaic system. FIG. 1 illustrates a diagram of a photovoltaic system, including a wire-based hanging wire-way for photovoltaic modules of the photovoltaic system, in accordance with an embodiment of the present invention.

Referring to FIG. 1, a photovoltaic system 100 includes a first photovoltaic module group 102 and a second photovoltaic module group 104. A wire-based hanging wire-way 106 is coupled with first photovoltaic module group 102 and second photovoltaic module group 104. A first bundle of electrical cables 108 is supported by wire-based hanging wire-way 106. In accordance with an embodiment of the present invention, one or more electrical cables from first bundle of electrical cables 108 is coupled to first photovoltaic module group 102. Photovoltaic system 100 also includes a power distribution network 110, which can also be referred to as a combiner box, adapted to receive a second bundle of electrical cables 112. In an embodiment, second bundle of electrical cables 112 includes first bundle of electrical cables 108. One or more electrical cables from second bundle of electrical cables 112 is coupled to second photovoltaic module group 104. In an embodiment, a second wire-based hanging wire-way is coupled with second photovoltaic module group 104 and power distribution network 110, as depicted in FIG. 1. In that embodiment, second bundle of electrical cables 112 is supported by the second wire-based hanging wire-way. In an alternative embodiment, a second wire-based hanging wire-way is not used and second bundle of electrical cables 112 is supported by other means, e.g., by burying second bundle of electrical cables 112 underground. It is to be understood that photovoltaic system 100 is not limited to two photovoltaic module groups. In accordance with an embodiment of the present invention, a photovoltaic system 100 includes a plurality of photovoltaic modules or module groups, each module or module group associated with electrical cables, and bundles of the electrical cables from the plurality of photovoltaic modules or module groups supported by a plurality of wire-based hanging wire-ways.

Wire-based hanging wire-way 106, and any additional wire-based hanging wire-ways, may be suspended from the ground, e.g. from the base of photovoltaic module groups 102 and 104, at a height suitable for a variety of applications. For example, in accordance with an embodiment of the present invention, wire-based hanging wire-way 106 is suspended from the ground at a height approximately in the range of 2-3 meters. In one embodiment, the height is selected to accommodate access by maintenance trucks. In another embodiment, the height for suspension need only be sufficient to accommodate local pests, such as rabbits. In accordance with an embodiment of the present invention, wire-based hanging wire-way 106 has an internal support based on tension between points, e.g. based on tension between photovoltaic module groups 102 and 104. In one embodiment, no further support for wire-based hanging wire-way 106, e.g., in one embodiment, moment resistance is not used in addition to tension. The electrical cables or bundles of electrical cables supported by wire-based hanging wire-way 106 may be suitable for use in the solar energy industry. For example, in accordance with an embodiment of the present invention, wire-based hanging wire-way 106 supports electrical cables configured for 600 Volts, 1000 Volts or 1200 Volts applications. In an embodiment, the suspension of the electrical cables or bundles of electrical cables supported by wire-based hanging wire-way 106 does not rely on the strength of the electrical cables or bundles of electrical cables. In a specific embodiment, wire-based hanging wire-way 106 includes a wire-line with support loops, as depicted in the magnified view box of FIG. 1. In a particular embodiment, the wire-line is braided.

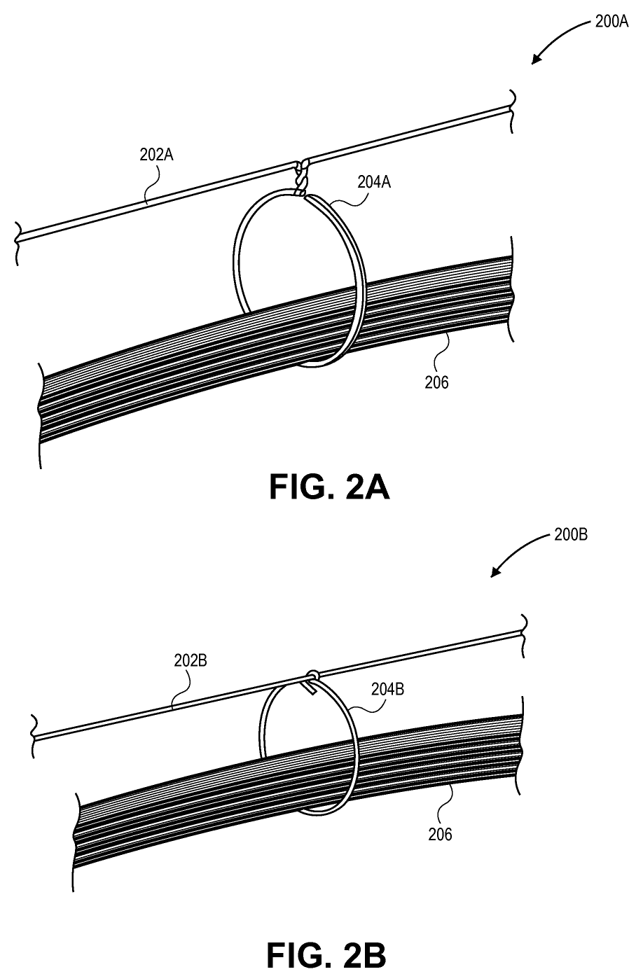

In the case where wire-based hanging wire-way 106 includes a wire-line with support loops, the support loops may be composed of, and even made from, the same material as the wire-line. For example, FIG. 2A illustrates an isometric view of a portion of a wire-based hanging wire-way for photovoltaic modules in a photovoltaic system, in accordance with an embodiment of the present invention.

Referring to FIG. 2A, a wire-based hanging wire-way 200A includes a wire-line 202A and a plurality of periodic twisted loops 204A (only one is shown in FIG. 2A) formed from and coupled to wire-line 202A. In accordance with an embodiment of the present invention, each twisted loop 204A is adapted to receive a bundle of electrical cables 206. In one embodiment, each twisted loop 204A is spaced from the next twisted loop by a distance approximately in the range of 0.25-2 meters. In one embodiment, each twisted loop 204A has a diameter approximately in the range of 0.02-0.2 meters. In a specific embodiment, the loop diameter of each twisted loop 204A changes along wire-line 202A, depending on thickness of the bundle of electrical cables 206 at a particular point, e.g. between specific photovoltaic module groups, in a photovoltaic system. In an embodiment, wire-line 202A and, hence, the plurality of periodic twisted loops 204A, is composed of a material such as, but not limited to galvanized steel, stainless steel, aluminum, plastic or clad copper. In a particular embodiment, the plurality of periodic twisted loops 204A is generated from wire-line 202A without breaking the continuity of wire-line 202A. In an embodiment, only after the fabrication of the plurality of periodic twisted loops 204A is wire-line 202A made discontinuous.

In the case where wire-based hanging wire-way 106 includes a wire-line with support loops, the support loops may be fabricated independent from the fabrication of the wire-line. FIG. 2B illustrates an isometric view of a portion of a wire-based hanging wire-way for photovoltaic modules in a photovoltaic system, in accordance with an embodiment of the present invention.

Referring to FIG. 2B, a wire-based hanging wire-way 200B includes a wire-line 202B and a plurality of periodic independent wire loops 204B (only one is shown in FIG. 2B) coupled to wire-line 202B. In accordance with an embodiment of the present invention, each independent wire loop 204B is adapted to receive a bundle of electrical cables 206. In one embodiment, each independent wire loop 204B is spaced from the next independent wire loop by a distance approximately in the range of 0.25-2 meters. In one embodiment, each independent wire loop 204B has a diameter approximately in the range of 0.02-0.2 meters. In a specific embodiment, the loop diameter of each independent wire loop 204B changes along wire-line 202B, depending on thickness of the bundle of electrical cables 206 at a particular point, e.g. between specific photovoltaic module groups, in a photovoltaic system. In an embodiment, wire-line 202B is composed of a material such as, but not limited to galvanized steel, stainless steel, aluminum, nylon or clad copper. In that embodiment, the plurality of periodic independent wire loops 204B is composed of a material such as, but not limited to galvanized steel, stainless steel, aluminum, plastic or clad copper. In a particular embodiment, the style of the plurality of periodic independent wire loops 204B coupled with wire-line 202B is referred to as a “barbed-wire” style.

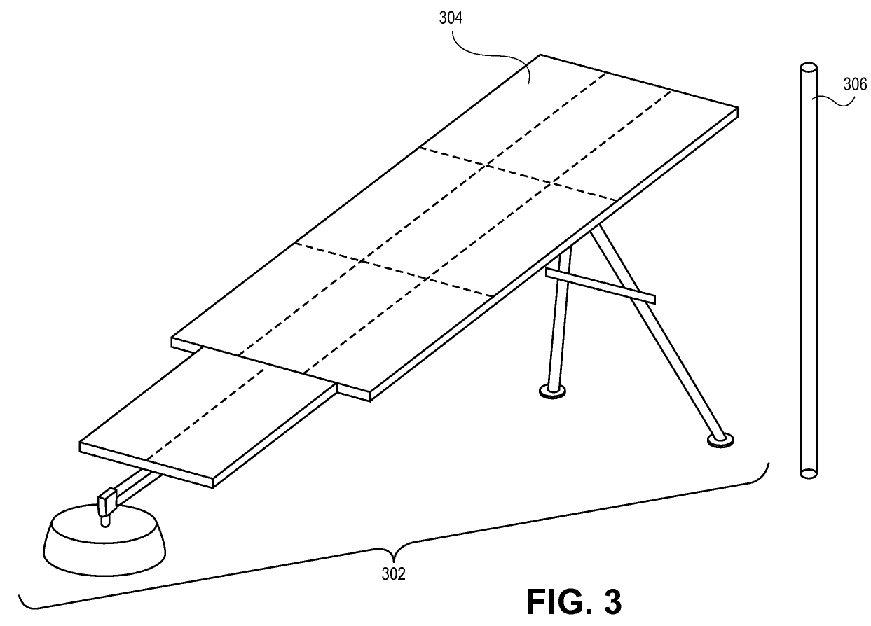

In an aspect of the present invention, a wire-based hanging wire-way may be coupled directly to a photovoltaic module, or module group, or coupled to a post or pole associated with a photovoltaic module or module group. FIG. 3 illustrates an isometric view of a photovoltaic module group assembled on a tracker and an associated post, in accordance with an embodiment of the present invention.

Referring to FIG. 3, a photovoltaic module group of a photovoltaic system includes a tracker 302, such as a T20 Tracker available from SunPower® Corp. of San Jose, Calif. The photovoltaic module group also includes an array of solar cells 304 supported by tracker 302. In accordance with an embodiment of the present invention, a wire-based hanging wire-way is coupled directly to a tracker, such as tracker 302, of a photovoltaic module group. However, in another embodiment, a photovoltaic module group is associated with a post, such as post 306 of FIG. 3, and a wire-based hanging wire-way is coupled directly to the post associated with the photovoltaic module group.

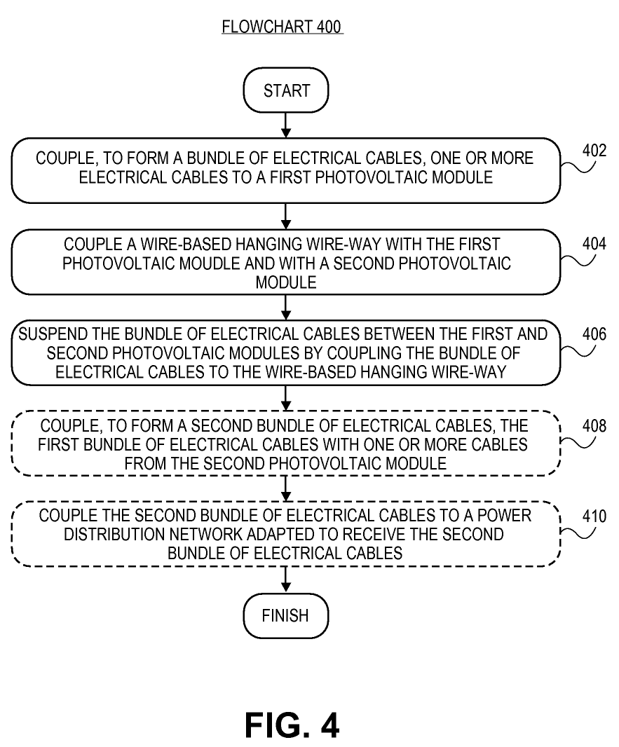

In an aspect of the present invention, a bundle of electrical cables may be supported by a wire-based hanging wire-way by first associating the bundle of electrical cables with the wire-based hanging wire-way and then suspending the wire-based hanging wire-way. FIG. 4 depicts a Flowchart 400 representing a series of operations in a method for supporting a bundle of electrical cables between photovoltaic modules, in accordance with an embodiment of the present invention.

Referring to operation 402 of Flowchart 400, a method for supporting a bundle of electrical cables between photovoltaic modules or module groups includes coupling, to form a bundle of electrical cables, one or more electrical cables to a first photovoltaic module. Referring to operation 404 of Flowchart 400, a wire-based hanging wire-way is then coupled with the first photovoltaic module and with a second photovoltaic module. In an embodiment, coupling the wire-based hanging wire-way with the first and second photovoltaic modules includes coupling the wire-based hanging wire-way directly to a tracker of the first photovoltaic module and directly to a tracker of the second photovoltaic module. In another embodiment, coupling the wire-based hanging wire-way with the first and second photovoltaic modules includes coupling the wire-based hanging wire-way directly to a post associated with the first photovoltaic module and directly to a post associated with the second photovoltaic module.

Referring to operation 406 of Flowchart 400, the bundle of electrical cables is then suspended between the first and second photovoltaic modules by coupling the bundle of electrical cables to the wire-based hanging wire-way. In an embodiment, coupling the bundle of electrical cables to the wire-based hanging wire-way includes placing the bundle of electrical cables in each loop of a plurality of periodic twisted loops formed from and coupled to a wire-line of the wire-based hanging wire-way. In another embodiment, coupling the bundle of electrical cables to the wire-based hanging wire-way includes placing the bundle of electrical cables in each loop of a plurality of periodic independent wire loops coupled to a wire-line of the wire-based hanging wire-way.

As described above, a bundle of electrical cables from a photovoltaic module or module group, or from a plurality of photovoltaic modules or module groups, may be coupled to a power distribution network, such as a combiner box. Thus, in accordance with an embodiment of the present invention, referring to an optional operation 408 of Flowchart 400, a method for supporting a bundle of electrical cables between photovoltaic modules further includes coupling, to form a second bundle of electrical cables, the first bundle of electrical cables with one or more cables from the second photovoltaic module. Then, referring to an optional operation 408 of Flowchart 400, the second bundle of electrical cables is coupled to a power distribution network adapted to receive the second bundle of electrical cables. In accordance with an embodiment of the present invention, a second wire-based hanging wire-way is used to couple the bundle of electrical cables from the photovoltaic module, or from the plurality of photovoltaic modules, to the power distribution network. In one embodiment, the second bundle of electrical cables is supported by the second wire-based hanging wire-way by first associating the second bundle of electrical cables with the second wire-based hanging wire-way and then suspending the second wire-based hanging wire-way. In a specific embodiment, the second wire-based hanging wire-way is coupled to a post associated with a power distribution network, such as a combiner box.

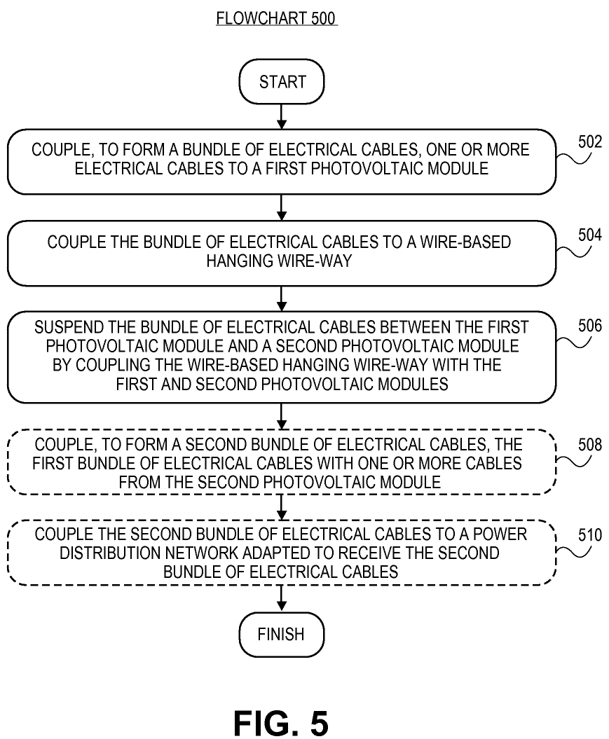

In another aspect of the present invention, a bundle of electrical cables may be supported by a wire-based hanging wire-way by first suspending the wire-based hanging wire-way and then associating the bundle of electrical cables with the wire-based hanging wire-way. FIG. 5 depicts a Flowchart 500 representing a series of operations in a method for supporting a bundle of electrical cables between photovoltaic modules, in accordance with an embodiment of the present invention.

Referring to operation 502 of Flowchart 500, a method for supporting a bundle of electrical cables between photovoltaic modules or module groups includes coupling, to form a bundle of electrical cables, one or more electrical cables to a first photovoltaic module. Referring to operation 504 of Flowchart 500, the bundle of electrical cables is coupled to a wire-based hanging wire-way. In an embodiment, coupling the bundle of electrical cables to the wire-based hanging wire-way includes placing the bundle of electrical cables in each loop of a plurality of periodic twisted loops formed from and coupled to a wire-line of the wire-based hanging wire-way. In another embodiment, coupling the bundle of electrical cables to the wire-based hanging wire-way includes placing the bundle of electrical cables in each loop of a plurality of periodic independent wire loops coupled to a wire-line of the wire-based hanging wire-way.

Referring to operation 506 of Flowchart 500, the bundle of electrical cables is suspended between the first photovoltaic module and a second photovoltaic module by coupling the wire-based hanging wire-way with the first and second photovoltaic modules. In an embodiment, coupling the wire-based hanging wire-way with the first and second photovoltaic modules includes coupling the wire-based hanging wire-way directly to a tracker of the first photovoltaic module and directly to a tracker of the second photovoltaic module. In another embodiment, coupling the wire-based hanging wire-way with the first and second photovoltaic modules includes coupling the wire-based hanging wire-way directly to a post associated with the first photovoltaic module and directly to a post associated with the second photovoltaic module.

As described above, a bundle of electrical cables from a photovoltaic module or module group, or from a plurality of photovoltaic modules or module groups, may be coupled to a power distribution network, such as a combiner box. Thus, in accordance with an embodiment of the present invention, referring to an optional operation 508 of Flowchart 500, a method for supporting a bundle of electrical cables between photovoltaic modules further includes coupling, to form a second bundle of electrical cables, the first bundle of electrical cables with one or more cables from the second photovoltaic module. Then, referring to an optional operation 508 of Flowchart 500, the second bundle of electrical cables is coupled to a power distribution network adapted to receive the second bundle of electrical cables. In accordance with an embodiment of the present invention, a second wire-based hanging wire-way is used to couple the bundle of electrical cables from the photovoltaic module, or from the plurality of photovoltaic modules, to the power distribution network. In one embodiment, the second bundle of electrical cables is supported by the second wire-based hanging wire-way by first suspending the second wire-based hanging wire-way and then associating the second bundle of electrical cables with the second wire-based hanging wire-way. In a specific embodiment, the second wire-based hanging wire-way is coupled to a post associated with a power distribution network, such as a combiner box.

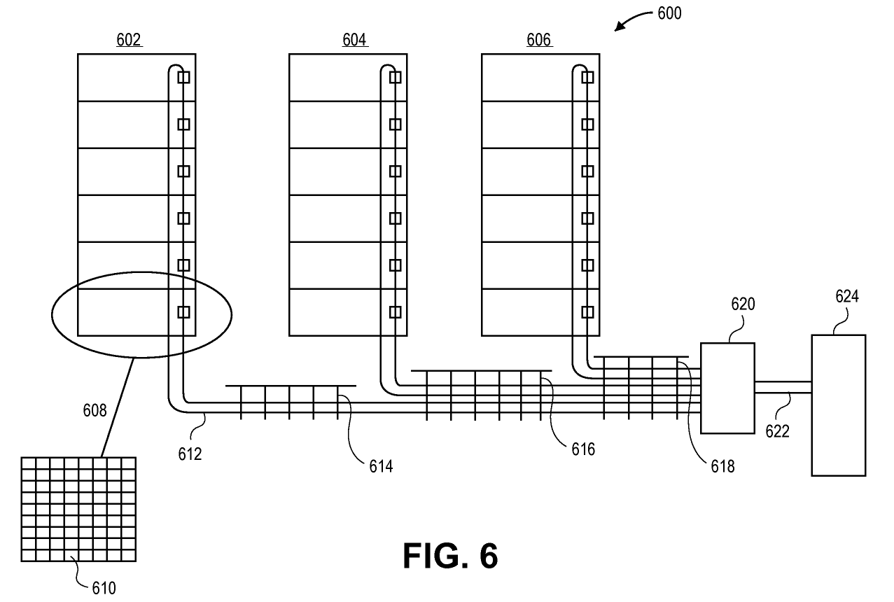

In yet another example of an embodiment of the present invention, FIG. 6 illustrates a diagram of a photovoltaic system, including a plurality of wire-based hanging wire-ways for photovoltaic module groups of the photovoltaic system.

Referring to FIG. 6, a photovoltaic system 600 includes a plurality of photovoltaic module groups 602, 604 and 606. Each module of each photovoltaic module group, e.g. module 608 which is shown in expanded view in FIG. 6, includes an array of solar cells 610. Each photovoltaic module group 602, 604 and 606 has an associated electrical cable or bundle of electrical cables, e.g., bundle of electrical cables 612 associated with photovoltaic module group 602. The electrical cable or bundle of electrical cables each photovoltaic module group 602, 604 and 606 is suspended in a plurality of wire-based hanging wire-ways, e.g., wire-based hanging wire-ways 614, 616 and 618 in FIG. 6. In accordance with an embodiment of the present invention, the size of each wire-based hanging wire-way expands with each successively larger bundle of electrical cables. For example, in one embodiment, wire-based hanging wire-way 618 is configured to receive electrical cables from all of photovoltaic module groups 602, 604 and 606, while wire-based hanging wire-way 614 is configured to receive electrical cables only from photovoltaic module group 602. The electrical cables from photovoltaic module groups 602, 604 and 606 are collected in combiner box 620 which connects the electrical cables in parallel. A high current line 622 couples combiner box 620 with an inverter 624. In an embodiment, inverter 624 combines lines from several combiner boxes and converts DC current to AC current.

Thus, a wire-based hanging wire-way for photovoltaic modules or module groups has been disclosed. In accordance with an embodiment of the present invention, a photovoltaic system includes a first and a second photovoltaic module or module group. A wire-based hanging wire-way is coupled with the first and the second photovoltaic modules. A first bundle of electrical cables is supported by the wire-based hanging wire-way. One or more electrical cables from the first bundle of electrical cables is coupled to the first photovoltaic module. The photovoltaic system also includes a power distribution network adapted to receive a second bundle of electrical cables, the second bundle of electrical cables including the first bundle of electrical cables. One or more electrical cables from the second bundle of electrical cables is coupled to the second photovoltaic module. In one embodiment, the wire-based hanging wire-way includes a wire-line and a plurality of periodic twisted loops formed from and coupled to the wire-line, each twisted loop adapted to receive the first bundle of electrical cables. In another embodiment, the wire-based hanging wire-way includes a wire-line and a plurality of periodic independent wire loops coupled to the wire-line, each independent wire loop adapted to receive the first bundle of electrical cables.

What is claimed is:

1. A photovoltaic system, comprising:
a first and a second photovoltaic module group;
a wire-based hanging wire-way coupled with the first and the second photovoltaic module groups;
a first bundle of electrical cables supported by the wire-based hanging wire-way, one or more electrical cables from the first bundle coupled to the first photovoltaic module group; and
a power distribution network adapted to receive a second bundle of electrical cables, the second bundle of electrical cables comprising the first bundle of electrical cables, and one or more electrical cables from the second bundle coupled to the second photovoltaic module group.

2. The photovoltaic system of claim 1, wherein the wire-based hanging wire-way comprises:
a wire-line; and
a plurality of periodic twisted loops formed from and coupled to the wire-line, each twisted loop adapted to receive the first bundle of electrical cables.

3. The photovoltaic system of claim 2, wherein each twisted loop is spaced from the next twisted loop by a distance approximately in the range of 0.25-2 meters, each twisted loop having a diameter approximately in the range of 0.02-0.2 meters.

4. The photovoltaic system of claim 1, wherein the wire-based hanging wire-way comprises:
a wire-line; and
a plurality of periodic independent wire loops coupled to the wire-line, each independent wire loop adapted to receive the first bundle of electrical cables.

5. The photovoltaic system of claim 4, wherein each independent wire loop is spaced from the next independent wire loop by a distance approximately in the range of 0.25-2 meters, each independent wire loop having a diameter approximately in the range of 0.02-0.2 meters.

6. The photovoltaic system of claim 1, wherein each of the first and a second photovoltaic module groups comprises a tracker, and wherein the wire-based hanging wire-way is coupled directly to the trackers of the first and a second photovoltaic module groups.

7. The photovoltaic system of claim 1, wherein each of the first and a second photovoltaic module groups is associated with a post, and wherein the wire-based hanging wire-way is coupled directly to the posts associated with the first and a second photovoltaic module groups.

8. The photovoltaic system of claim 1, further comprising:
a second wire-based hanging wire-way coupled with the second photovoltaic module group and the power distribution network, the second bundle of electrical cables supported by the second wire-based hanging wire-way.

9. A method for supporting a bundle of electrical cables between photovoltaic modules or module groups, comprising:
coupling, to form a bundle of electrical cables, one or more electrical cables to a first photovoltaic module group;
coupling a wire-based hanging wire-way with the first photovoltaic module group and with a second photovoltaic module group; and
suspending the bundle of electrical cables between the first and second photovoltaic module groups by coupling the bundle of electrical cables to the wire-based hanging wire-way.

10. The method of claim 9, wherein coupling the bundle of electrical cables to the wire-based hanging wire-way comprises placing the bundle of electrical cables in each loop of a plurality of periodic twisted loops formed from and coupled to a wire-line of the wire-based hanging wire-way.

11. The method of claim 9, wherein coupling the bundle of electrical cables to the wire-based hanging wire-way comprises placing the bundle of electrical cables in each loop of a plurality of periodic independent wire loops coupled to a wire-line of the wire-based hanging wire-way.

12. The method of claim 9, wherein coupling the wire-based hanging wire-way with the first and second photovoltaic module groups comprises coupling the wire-based hanging wire-way directly to a tracker of the first photovoltaic module group and directly to a tracker of the second photovoltaic module group.

13. The method of claim 9, wherein coupling the wire-based hanging wire-way with the first and second photovoltaic module groups comprises coupling the wire-based hanging wire-way directly to a post associated with the first photovoltaic module group and directly to a post associated with the second photovoltaic module group.

14. The method of claim 9, further comprising:
coupling, to form a second bundle of electrical cables, the first bundle of electrical cables with one or more cables from the second photovoltaic module group; and
coupling the second bundle of electrical cables to a power distribution network adapted to receive the second bundle of electrical cables.

15. A method for supporting a bundle of electrical cables between photovoltaic modules or module groups, comprising:
coupling, to form a bundle of electrical cables, one or more electrical cables to a first photovoltaic module group;
coupling the bundle of electrical cables to a wire-based hanging wire-way; and
suspending the bundle of electrical cables between the first photovoltaic module group and a second photovoltaic module group by coupling the wire-based hanging wire-way with the first and second photovoltaic module groups.

16. The method of claim 15, wherein coupling the bundle of electrical cables to the wire-based hanging wire-way comprises placing the bundle of electrical cables in each loop of a plurality of periodic twisted loops formed from and coupled to a wire-line of the wire-based hanging wire-way.

17. The method of claim 15, wherein coupling the bundle of electrical cables to the wire-based hanging wire-way comprises placing the bundle of electrical cables in each loop of a plurality of periodic independent wire loops coupled to a wire-line of the wire-based hanging wire-way.

18. The method of claim 15, wherein coupling the wire-based hanging wire-way with the first and second photovoltaic module groups comprises coupling the wire-based hanging wire-way directly to a tracker of the first photovoltaic module group and directly to a tracker of the second photovoltaic module group.

19. The method of claim 15, wherein coupling the wire-based hanging wire-way with the first and second photovoltaic module groups comprises coupling the wire-based hanging wire-way directly to a post associated with the first photovoltaic module group and directly to a post associated with the second photovoltaic module group.

20. The method of claim 15, further comprising:
coupling, to form a second bundle of electrical cables, the first bundle of electrical cables with one or more cables from the second photovoltaic module group; and
coupling the second bundle of electrical cables to a power distribution network adapted to receive the second bundle of electrical cables.
